(19) United States
(12) Patent Application Publication
(10) Pub. No.: US 2025/0120159 A1
(43) Pub. Date: Apr. 10, 2025

(54) METHOD FOR FORMING THIN FILM TRANSISTOR

(71) Applicant: Electronics and Telecommunications Research Institute, Daejeon (KR)

(72) Inventors: Sung Haeng CHO, Daejeon (KR); Chihun SUNG, Daejeon (KR); Sooji NAM, Daejeon (KR)

(21) Appl. No.: 18/887,701

(22) Filed: Sep. 17, 2024

(30) Foreign Application Priority Data
Oct. 6, 2023 (KR) 10--2023-0133574
Jul. 8, 2024 (KR) 10-1024-0089798

(51) Int. Cl. H01L 29/417; H01L 29/423; H01L 29/66; H01L 29/786

(52) U.S. Cl. CPC H10D 64/258; H10D 30/6729; H10D 30/673; H10D 30/6755; H10D 30/6757; H10D 99/00

(57) ABSTRACT

Provided is a thin film transistor including a substrate, a channel layer on the substrate, a first source/drain electrode and a second source/drain electrode spaced apart on the substrate and on the channel layer in a first direction parallel to the substrate, a gate insulation layer on the substrate, the channel layer, the first source/drain electrode, and the second source/drain electrode, and a gate electrode on the gate insulation layer between the first and second source/drain electrodes, wherein the uppermost level of the gate electrode is substantially the same as the uppermost level of the gate insulation layer.

### CROSS-REFERENCE TO RELATED APPLICATIONS

This U.S. non-provisional patent application claims priority under 35 U.S.C. § 119 of Korean Patent Application Nos. 10-2023-0133574, filed on Oct. 6, 2023, and 10-2024-0089798, filed on Jul. 8, 2024, the entire contents of which are hereby incorporated by reference.

### BACKGROUND

The present disclosure herein relates to a method for forming a thin film transistor, and more particularly, to a method for forming a nano-channel thin film transistor with minimized parasitic capacitance between a gate electrode and source/drain electrodes.

The performance of semiconductor devices may be improved by increasing the degree of integration of elements such as transistors or lowering the driving voltage of the elements. A representative method that has been used so far to this end is a technique of using a light-sensitive photoresist for transferring an element pattern to be constituted, and the minimum size of the pattern to be patterned is determined according to the wavelength of the light used at this time. For example, if the deep ultraviolet (DUV) wavelength (about 193 nm) of the ArF laser or the extreme ultraviolet (EUV) wavelength of 13.5 nm is used, patterns from tens of nanometers to several nanometers may be respectively formed, and the technique is currently commercially available. However, in the case of such DUV and EUV lithography equipment, an applicable substrate is limited to 12-inch (about 300 mm) wafers, which are costly. However, recently, due to the spread of IoT, etc., the areas of use of semiconductor devices have increased exponentially, and the demand for improved semiconductor performance for the use of artificial intelligence, big data, and the like is surpassing the speed of the development of semiconductor integration technology at the two-dimensional level that has been commonly known as Moore's Law.

### SUMMARY

The present disclosure provides a thin film transistor with improved performance by minimizing parasitic capacitance between a gate electrode and a source/drain electrode.

The present disclosure also provides patterns of several nanometers to tens of nanometers formed by using mixed light of existing g-line (about 436 nm), h-line (about 405 nm), and i-line (about 365 nm), thereby reducing processing costs.

The objects to be achieve by the inventive concept are not limited to the above-mentioned objects, and other objects that are not mentioned may be apparent to those skilled in the art from the following description.

An embodiment of the inventive concept provides a thin film transistor including a substrate, a channel layer on the substrate, a first source/drain electrode and a second source/drain electrode spaced apart on the substrate and on the channel layer in a first direction parallel to the substrate, a gate insulation layer on the substrate, the channel layer, the first source/drain electrode, and the second source/drain electrode, and a gate electrode on the gate insulation layer between the first and second source/drain electrodes, wherein the uppermost level of the gate electrode is substantially the same as the uppermost level of the gate insulation layer.

In an embodiment of the inventive concept, a method for manufacturing a thin film transistor includes sequentially stacking a channel layer and a source/drain layer on a substrate, etching the source/drain layer to form first and second source/drain electrodes on the channel layer, sequentially stacking a gate insulation layer and a gate electrode layer on the channel layer and the first and second source/drain electrodes, and etching a portion of the gate electrode layer to form a gate electrode on the gate insulation layer between the first and second source/drain electrodes, wherein the uppermost level of the gate electrode is substantially the same as the uppermost level of the gate insulation layer.

Specific details of other embodiments are included in the detailed description and drawings.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is a cross-sectional view showing a thin film transistor according to an embodiment of the inventive concept;

FIG. 2 is a flowchart showing a method for manufacturing a thin film transistor according to embodiments of the inventive concept;

FIG. 3, FIG. 5, FIG. 7, FIG. 9, FIG. 11, FIG. 13, FIG. 15, FIG. 17, FIG. 19, FIG. 21, FIG. 23, FIG. 25, FIG. 27, and FIG. 29 are plan views showing a method for manufacturing a thin film transistor according to embodiments of the inventive concept; and

FIG. 4, FIG. 6, FIG. 8, FIG. 10, FIG. 12, FIG. 14, FIG. 16, FIG. 18, FIG. 20, FIG. 22, FIG. 24, FIG. 26, FIG. 28, and FIG. 30 are cross-sectional views showing a method for manufacturing a thin film transistor according to embodiments the inventive concept.

### DETAILED DESCRIPTION

With reference to the following drawings, a method for manufacturing a thin film transistor according to embodiments of the inventive concept will be described in detail.

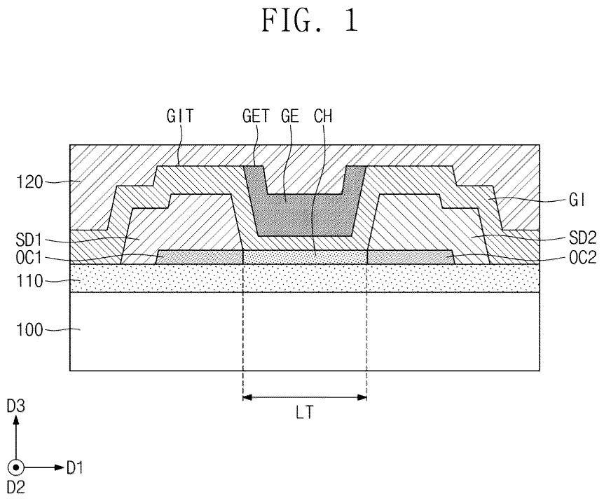

FIG. 1 is a cross-sectional view showing a thin film transistor according to an embodiment of the inventive concept.

Referring to FIG. 1, a buffer layer 110 may be provided on a substrate 100. The substrate 100 may be an opaque substrate by including an opaque material. As an example, the substrate 100 may be a silicon substrate. The buffer layer 110 may be stacked to a substantially uniform thickness. The buffer layer 110 may include an insulation material. As an example, the buffer layer 110 may include at least one of silicon oxide, silicon oxynitride, or aluminum nitride. As an example, the buffer layer 110 may be omitted.

A channel layer CH may be provided on the buffer layer 110. The channel layer CH may be stacked to a substantially uniform thickness, and the top surface of the channel layer CH may be parallel to the top surface of the substrate 100. When viewed in a plan perspective, the channel layer CH may have a bar shape extending in a first direction D1 parallel to the substrate 100.

The channel layer CH may include an oxide semiconductor. As an example, the oxide semiconductor may include at least one of indium zinc oxide (IZO), indium gallium zinc oxide (IGZO), indium zinc tin oxide (IZTO), aluminum-doped indium zinc tin oxide (AIZTO), zinc tin oxide (ZTO), or combinations thereof.

First and second source/drain electrodes SD1 and SD2 may be provided on the channel layer CH and the buffer layer 110. As the first and second source/drain electrodes SD1 and SD2 move away from the substrate 100 in a third direction D3 perpendicular to the substrate 100, the length of the first and second source/drain electrodes SD1 and SD2 may decrease in the first direction D1 and a second direction D2 perpendicular to the first direction D1. In other words, as the first and second source/drain electrodes SD1 and SD2 move closer to the substrate 100, the area of cross-sections of the first and second source/drain electrodes SD1 and SD2 cut in the first direction D1 and the second direction D2 may increase.

A region of the first and second source/drain electrodes SD1 and SD2 vertically overlapping the channel layer CH may be formed to be higher, by the thickness of the channel layer CH in the third direction D3, than a region vertically overlapping the buffer layer 110. In other words, the region of the first and second source/drain electrodes SD1 and SD2 vertically overlapping the channel layer CH may have a structure of further protruding by the thickness of the channel layer CH than the region vertically overlapping the buffer layer 110.

The first and second source/drain electrodes SD1 and SD2 may be spaced apart from each other by a first a distance LT in the first direction D1. As an example, the first distance LT may be about 20 nm to about 2500 nm.

The first and second source/drain electrodes SD1 and SD2 may include a metal material. As an example, the metal material may include at least one of copper (Cu), molybdenum (Mo), titanium (Ti), tantalum (Ta), nickel (Ni), gold (Au), silver (Ag), aluminum (Al), platinum (Pt), tungsten (W), titanium nitride (TiN), or combinations thereof. As an example, the first and second source/drain electrodes SD1 and SD2 may include either indium zinc oxide (IZO) or indium tin oxide (ITO), which is a transparent electrode.

In the channel layer CH, a first ohmic contact region OC1 may be provided in a region to which the first source/drain electrode SD1 and the channel layer CH are adjacent, and a second ohmic contact region OC2 may be provided in a region to which the second source/drain electrode SD2 and the channel layer CH are adjacent. The first ohmic contact region OC1 and the second ohmic contact region OC2 in the channel layer CH may be spaced apart from each other by the first direction LT in the first direction D1 parallel to the substrate 100. The first and second ohmic contact regions OC1 and OC2 may serve to make the connection between the channel layer CH and the first and second source/drain electrodes SD1 and SD2 as an ohmic bonding.

A gate insulation layer GI may be provided on the substrate 100, the first and second source/drain electrodes SD1 and SD2, and the channel layer CH. The thickness of the gate insulation layer GI may be substantially uniform. The gate insulation layer GI may include an insulation material. As an example, the insulation material may include at least one of silicon oxide, silicon oxynitride, or aluminum nitride.

A gate electrode GE may be provided on the gate insulation layer GI. The gate electrode GE may be provided at a position vertically spaced apart from the channel layer CH, and may not be provided at a position vertically spaced apart from the first and second source/drain electrodes SD1 and SD2. In other words, the gate electrode GE may be positioned on the gate insulation layer GI between the first and second source/drain electrodes SD1 and SD2, and the gate electrode GE may not be positioned vertically above the first and second source/drain electrodes SD1 and SD2. That is, the gate electrode GE may not vertically overlap the first and second source/drain electrodes SD1 and SD2, and may vertically overlap the channel layer CH between the first and second source/drain electrodes SD1 and SD2.

Since the gate electrode GE according to an embodiment of the inventive concept is spaced apart from the first and second source/drain electrodes SD1 and SD2 in the first direction D1 and the third direction D3, the distance between the gate electrode GE and the first and second source/drain electrodes SD1 and SD2 may be greater than if the gate electrode GE is spaced apart from the first and second source/drain electrodes SD1 and SD2 in the third direction D3. Accordingly, since the overlapping portion between the gate electrode GE and the first and second source/drain electrodes SD1 and SD2 is reduced or eliminated, the parasitic capacitance between the gate electrode GE and the first and second source/drain electrodes SD1 and SD2 may be reduced.

The lowermost level of the gate electrode GE spaced apart from the channel layer CH in the third direction D3 may be positioned at a level lower than the uppermost level of the first and second source/drain electrodes SD1 and SD2. The gate electrode GE may include the metal material.

An uppermost surface GET of the gate electrode may be coplanar with an uppermost surface GIT of the gate insulation layer. In other words, the uppermost surface GET of the gate electrode and the uppermost surface GIT of the gate insulation layer may be positioned at the same level.

Since the gate electrode GE is formed after the first and second source/drain electrodes SD1 and SD2 are formed, the gate electrode GE may be formed self-aligned to the first and second source/drain electrodes SD1 and SD2. That is, unlike the case in which the first and second source/drain electrodes SD1 and SD2 are formed according to the position of the gate electrode GE, the gate electrode GE may be provided aligned according to the positions of the first and second source/drain electrodes SD1 and SD2. Accordingly, the maximum width of the gate electrode GE may be less than the distance between the first and second source/drain electrodes.

An interlayer insulation layer 120 may be provided on the gate electrode GE and the gate insulation layer GI. The interlayer insulation layer 120 may include the above-described insulation material.

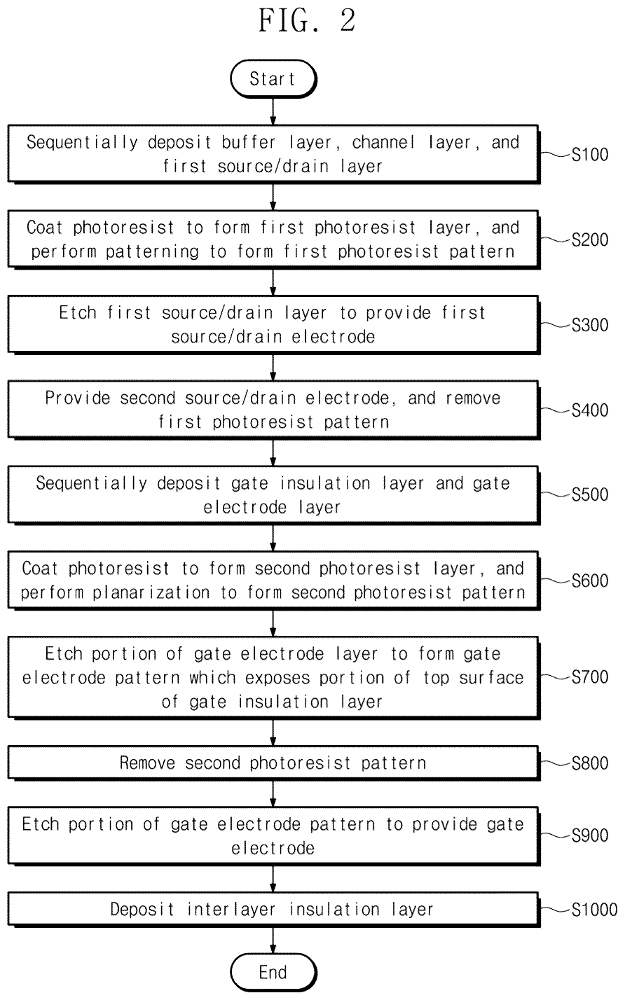

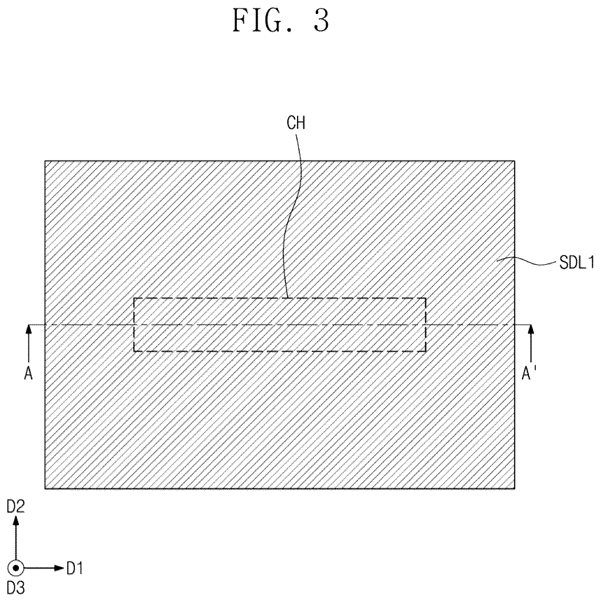

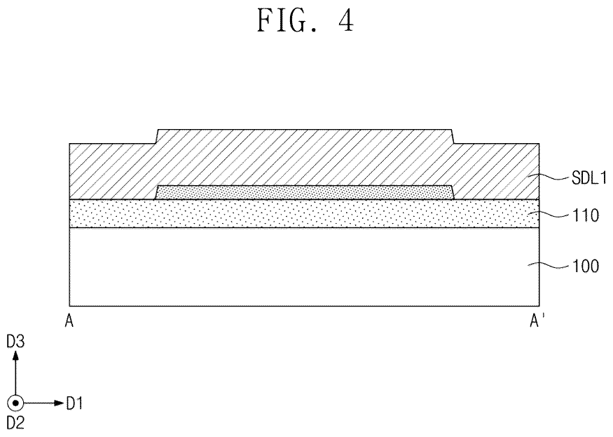

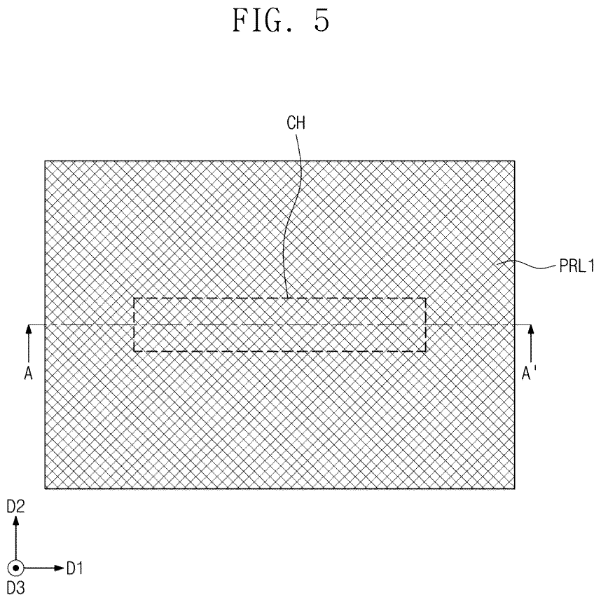

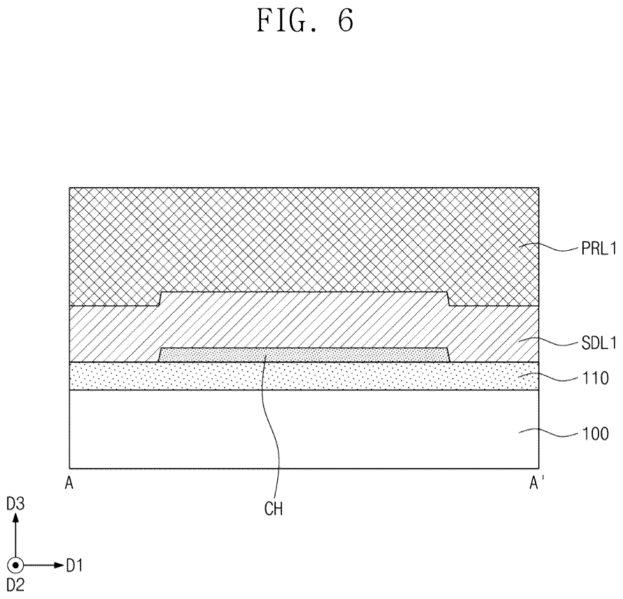

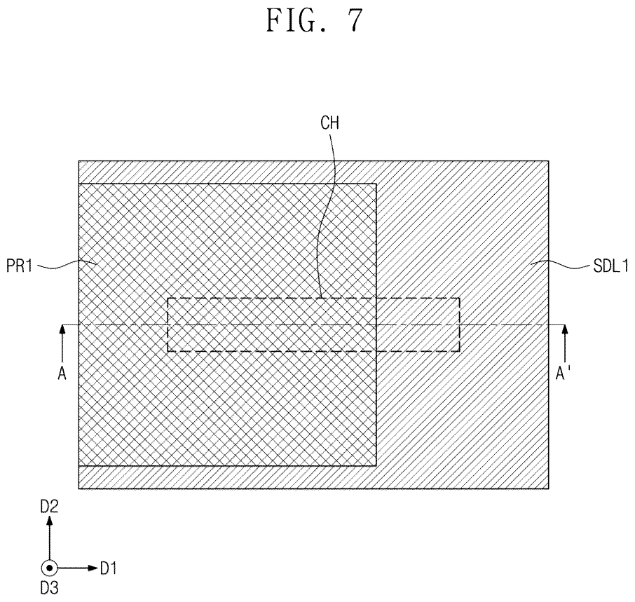

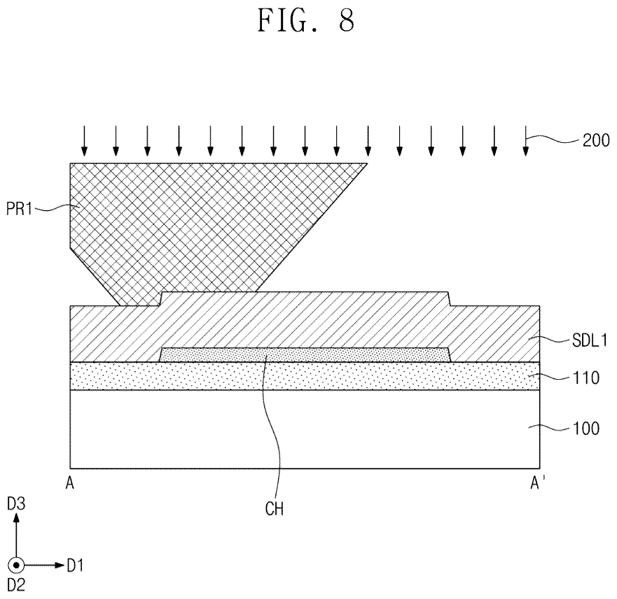

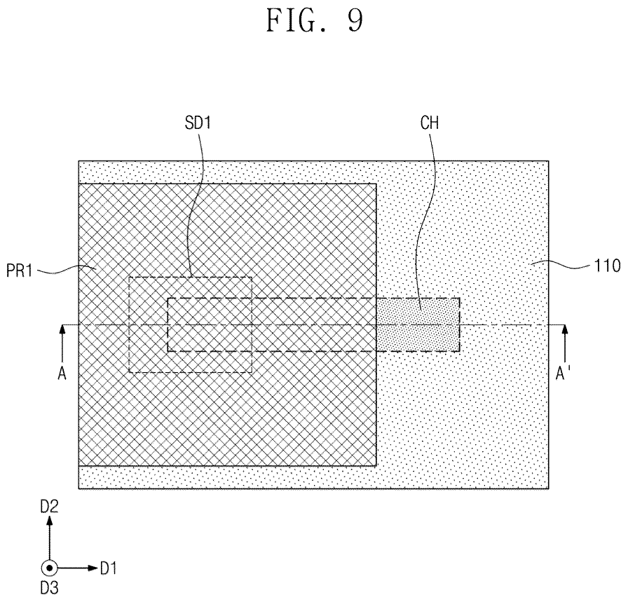

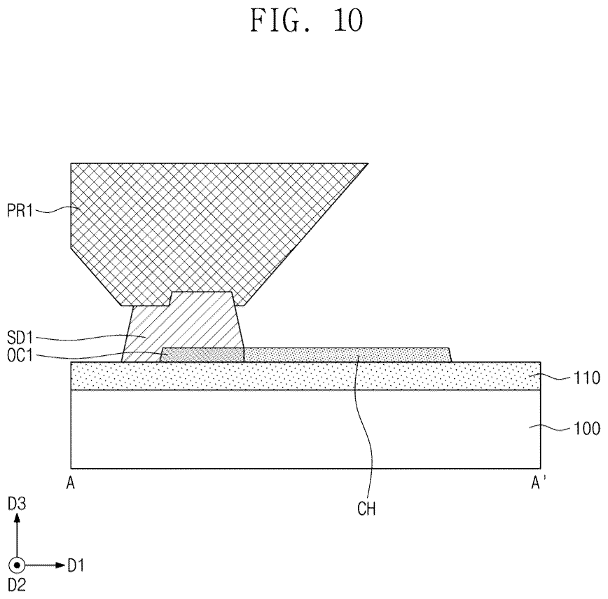

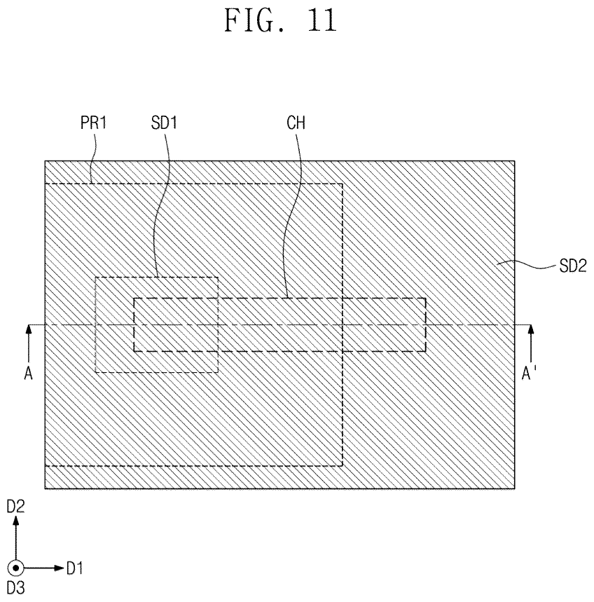

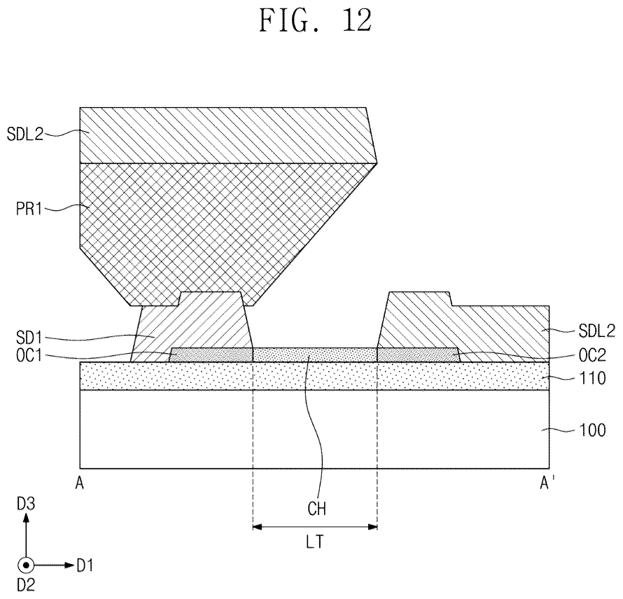

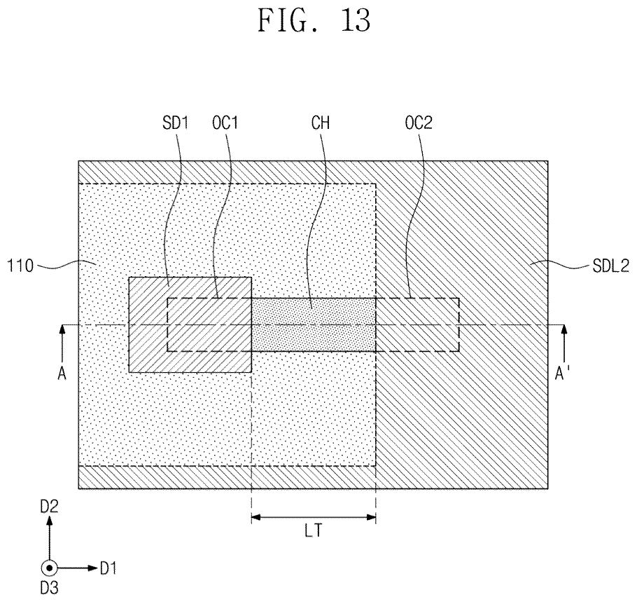

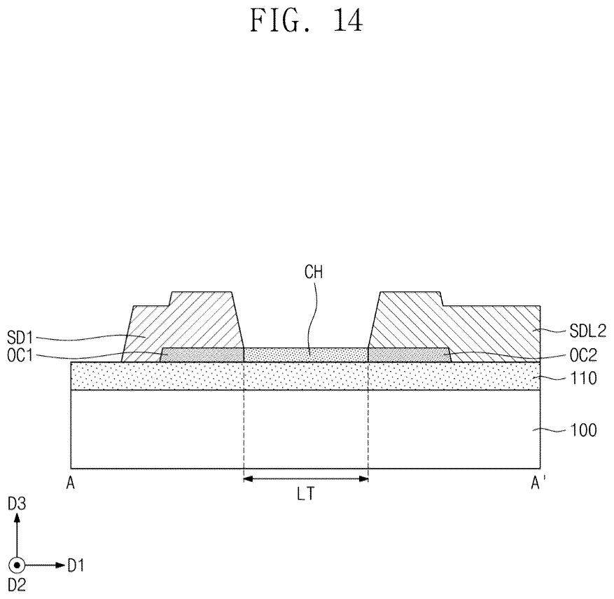

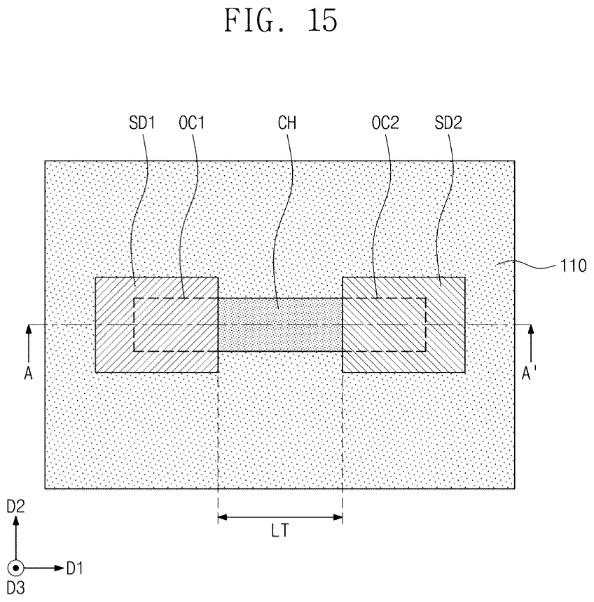

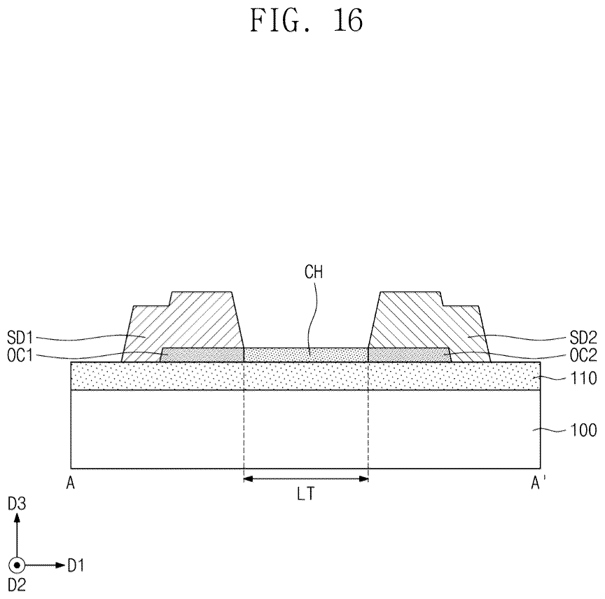

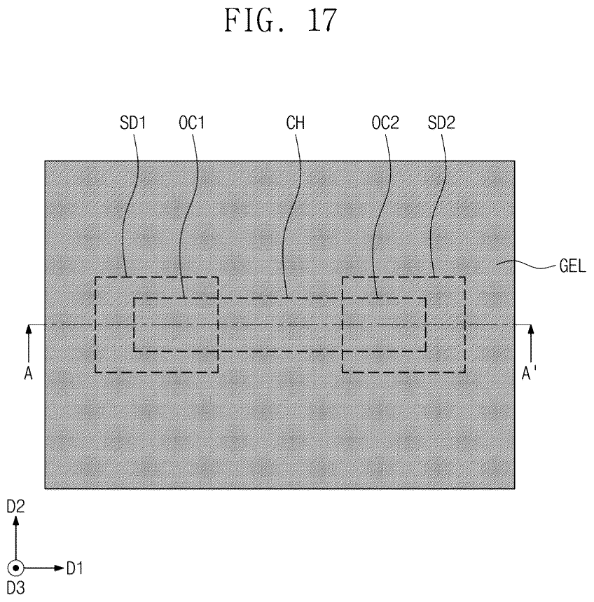

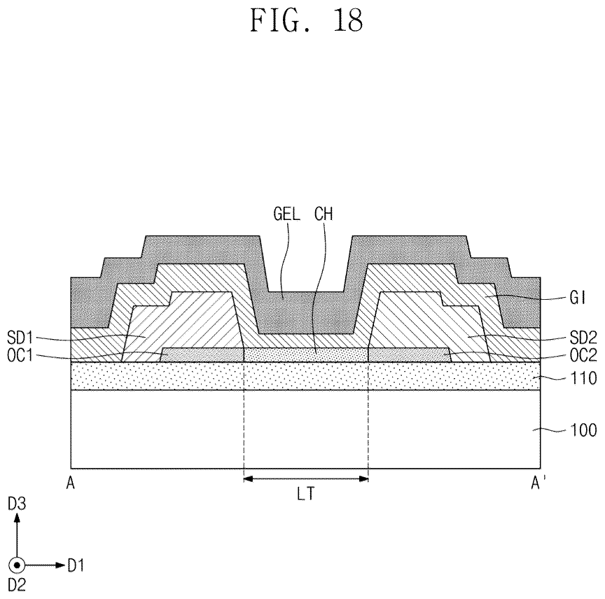

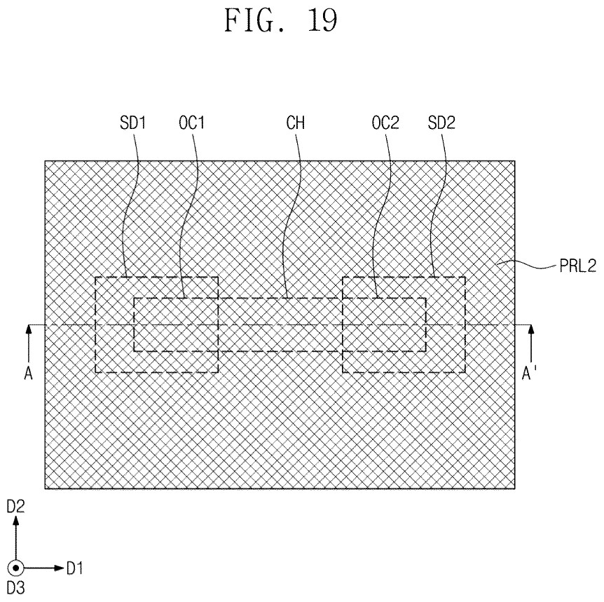

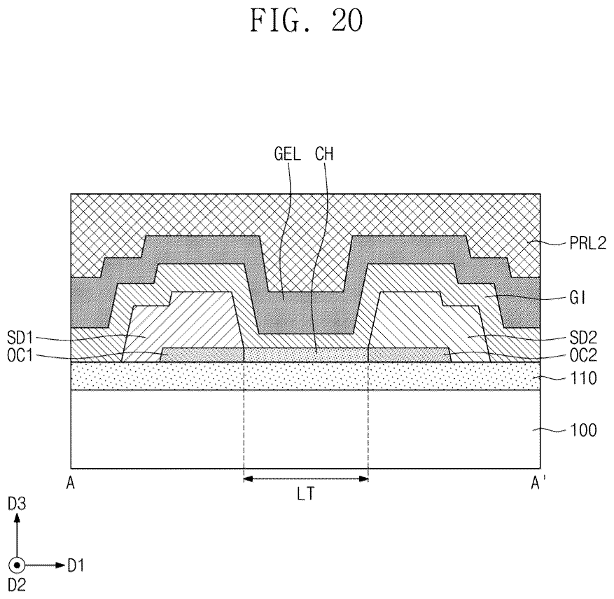

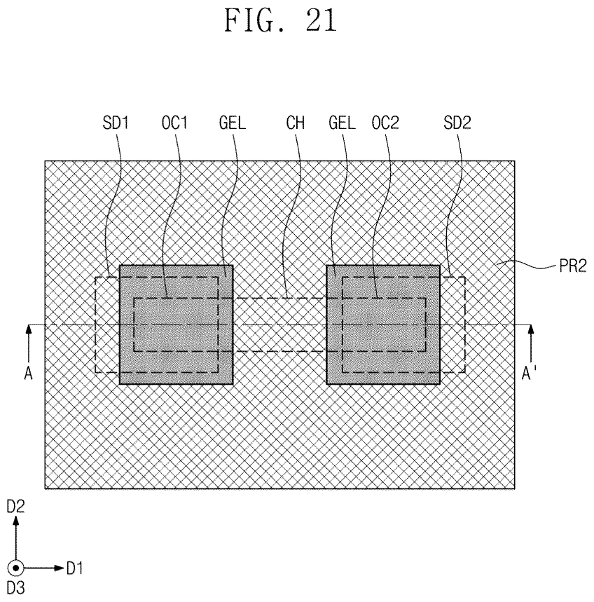

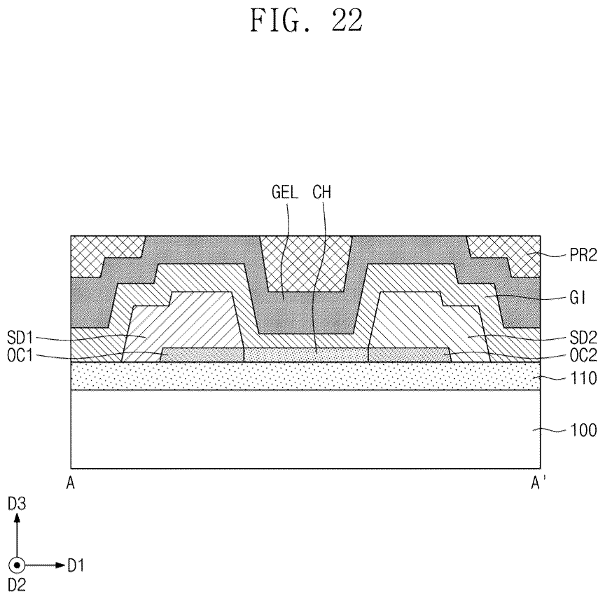

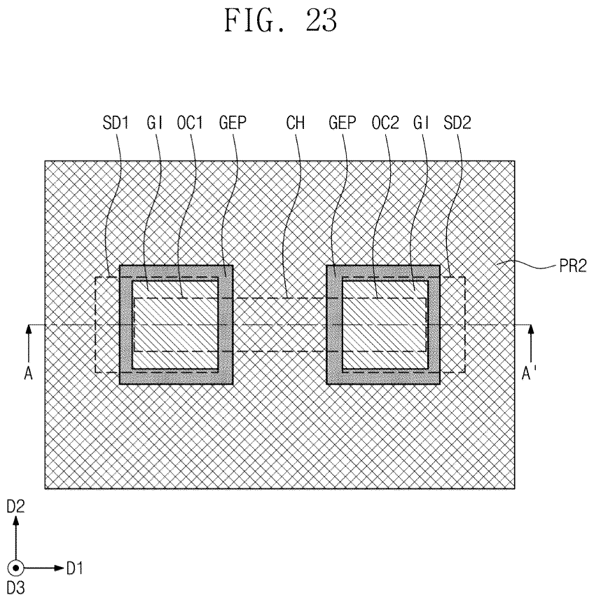

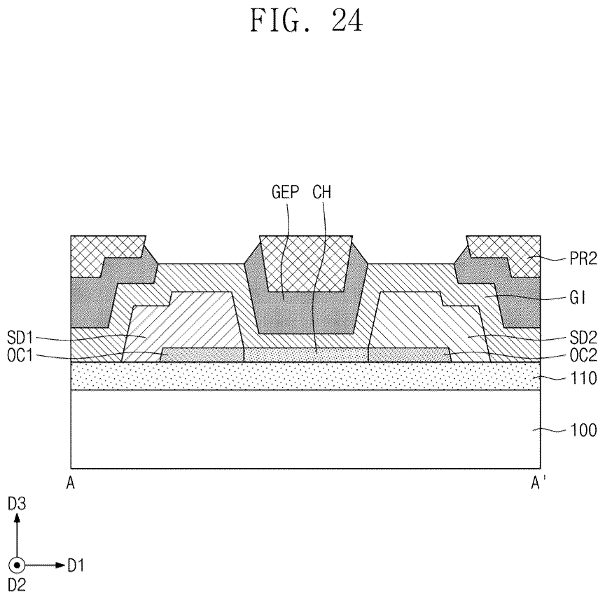

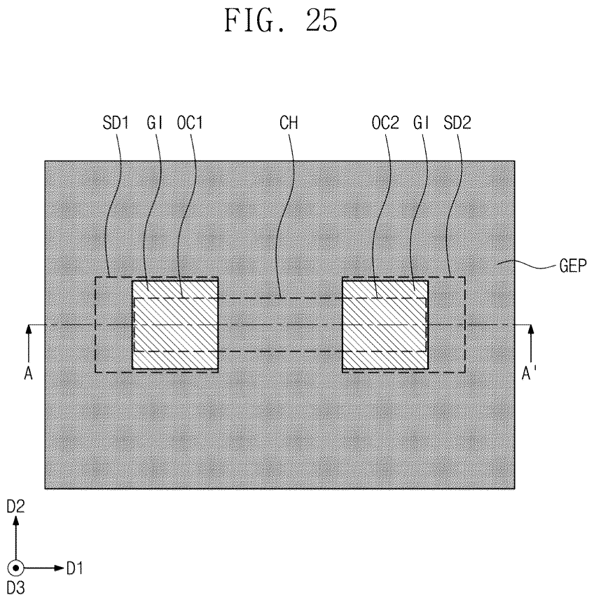

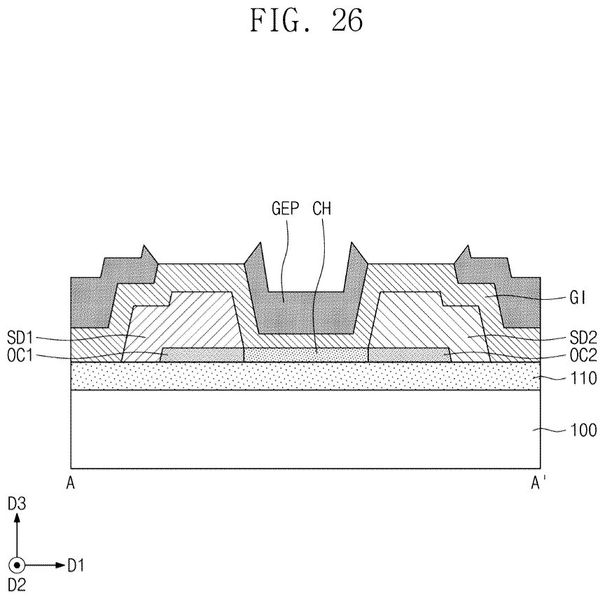

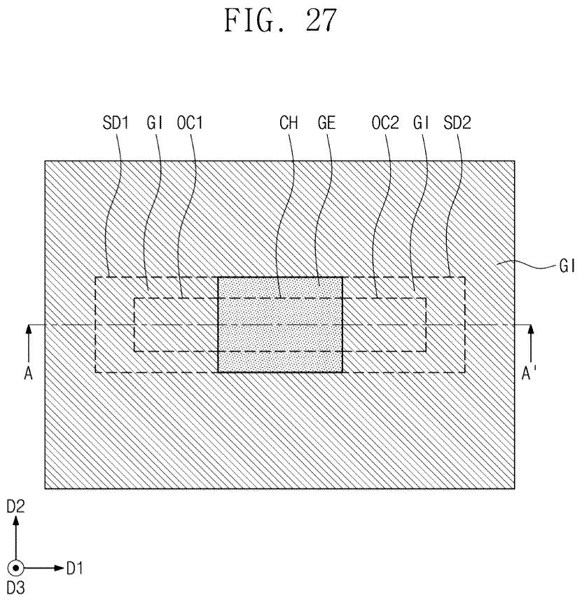

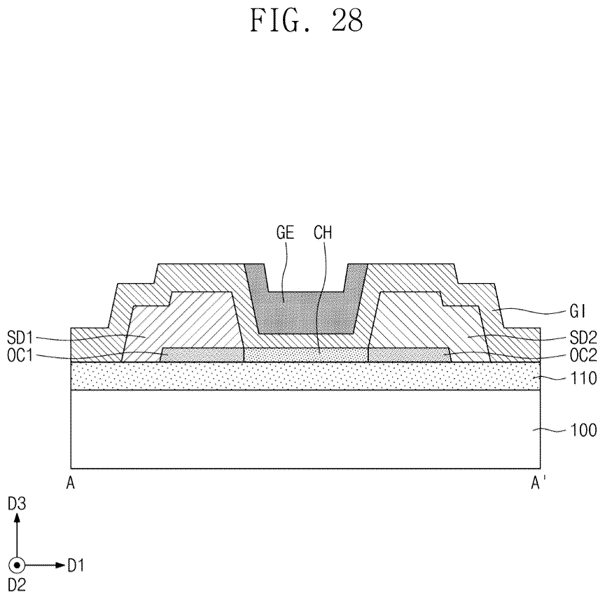

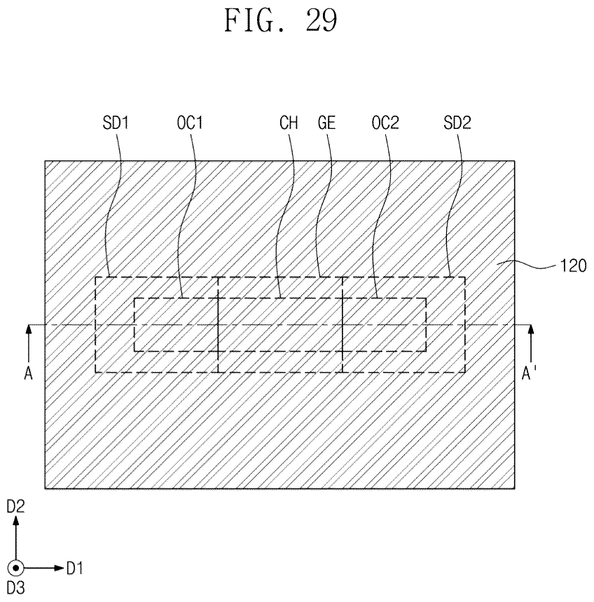

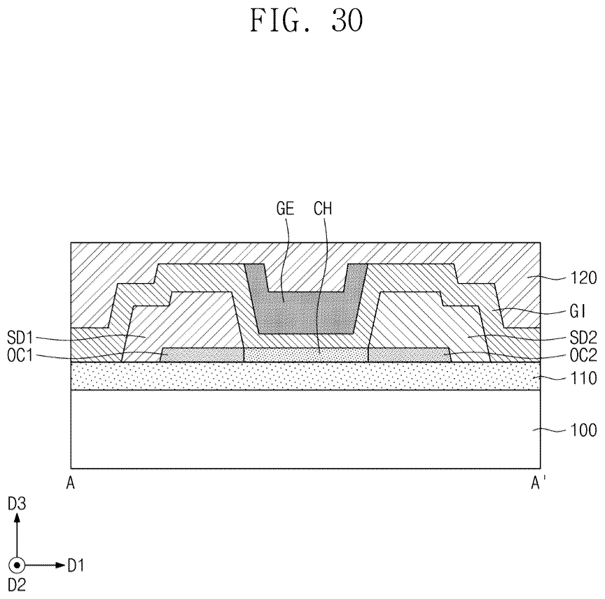

FIG. 2 is a flowchart showing a method for manufacturing a thin film transistor according to embodiments of the inventive concept. FIG. 3, FIG. 5, FIG. 7, FIG. 9, FIG. 11, FIG. 13, FIG. 15, FIG. 17, FIG. 19, FIG. 21, FIG. 23, FIG. 25, FIG. 27, and FIG. 29 are plan views showing a method for manufacturing a thin film transistor according to embodiments of the inventive concept. FIG. 4, FIG. 6, FIG. 8, FIG. 10, FIG. 12, FIG. 14, FIG. 16, FIG. 18, FIG. 20, FIG. 22, FIG. 24, FIG. 26, FIG. 28, and FIG. 30 are cross-sectional views showing a method for manufacturing a thin film transistor according to embodiments the inventive concept.

Referring to FIG. 2, FIG. 3, and FIG. 4, an opaque substrate 100 may be provided. As an example, the substrate 100 may be a silicon substrate. A buffer layer 110, a channel layer CH, and a first source/drain layer SDL1 may be sequentially stacked on the substrate 100 S100. The buffer layer 110, the channel layer CH, and the first source/drain layer SDL1 may be deposited through a deposition process or a thin-film adhesion process. As an example, the deposition process may be physical vapor deposition, chemical vapor deposition, or atomic layer deposition.

The buffer layer 110 may include an insulation material. As an example, the buffer layer 110 may include at least one of silicon oxide, silicon oxynitride, or aluminum nitride. As an example, the deposition process of the buffer layer 110 may be omitted.

The first source/drain layer SDL1 may include a metal material. As an example, the metal material may include at least one of copper (Cu), molybdenum (Mo), titanium (Ti), tantalum (Ta), nickel (Ni), gold (Au), silver (Ag), aluminum (Al), platinum (Pt), tungsten (W), titanium nitride (TiN), or combinations thereof. As an example, the first source/drain layer SDL1 may include either indium zinc oxide (IZO) or indium tin oxide (ITO), which is a transparent electrode.

Referring to FIG. 2, FIG. 5, and FIG. 6, a photoresist may be coated on the first source/drain layer SDL1 to form a first photoresist layer PRL1 S200. The first photoresist layer PRL1 may be formed by using, for example, a spin coating process, a slit coating process, or a slit and spin coating process. As an example, the photoresist may include a negative-type photoresist. As an example, the photoresist may include a polymer, a photoacid generator, and a solvent.

Referring to FIG. 2, FIG. 7, and FIG. 8, after the first photoresist layer PRL1 is formed, the first photoresist layer PRL1 may be patterned to form a first photoresist pattern PR1 S200. The patterning of the first photoresist layer PRL1 may include performing an exposure process and a development process on the first photoresist layer PRL1. During the exposure process for the first photoresist layer PRL1, light 200 may be irradiated vertically from the vertical upward of the substrate 100 toward the top surface of the substrate 100. As an example, the light 200 may be G-line (about 436 nm), H-line (about 405 nm), I-line (about 365 nm), mixed light thereof, or ultraviolet light. A portion of the first photoresist layer PRL1 may be cured by absorbing light L. As an example, the light 200 may generate an acid through the photoacid generator included in the photoresist, and the acid may aggregate the polymer inside the photoresist.

After the first photoresist layer PRL1 is irradiated with the light 200, the development process may be performed to remove the other portion of the first photoresist layer PRL1 that has not been irradiated with the light 200. The development process may include applying a developing solution on the first photoresist layer PRL1 to remove a portion of the first photoresist layer PRL1 that has not been cured. A portion of the cured first photoresist layer PRL1 may remain while the development process is performed and form the first photoresist pattern PR1. Prior to performing the development process, a soft bake process may be performed to heat and dry the partially cured first photoresist layer PRL1.

The first photoresist pattern PR1 may have a tapered shape. In other words, sidewalls of the first photoresist pattern PR1 may be inclined with respect to the top surface of the substrate 100. If the first photoresist pattern PR1 includes a negative photoresist, the length of the first photoresist patterns PR1 in the first direction D1 and the length thereof in the second direction D2 may decrease as the first photoresist patterns PR1 move closer to the top surface of the substrate 100. The slope of a sidewall of the first photoresist pattern PR1 may be controlled by adjusting the intensity, exposure time, and development time of the light 200.

Referring to FIG. 2, FIG. 9, and FIG. 10, the first source/drain layer SDL1 may be etched using the first photoresist pattern PRI as an etch mask to provide a first source/drain electrode SD1 S300. The etching process may include a wet etching process or a dry etching process. The first source/drain electrode SD1 may vertically overlap the first photoresist pattern PR1, and may be provided adjacent to the bottom surface of the first photoresist pattern PR1. The first source/drain electrode SD1 may have a narrower width as the first source/drain electrode SD1 moves away from the top surface of the substrate 100.

A first ohmic contact region OC1 may be formed in a region in which the first source/drain electrode SD1 meets the channel layer CH. The channel layer CH including an oxide semiconductor may form an oxygen vacancy when brought into contact with the first source/drain electrode SD1 including a metal material, and due to the oxygen vacancy, the doping concentration of the channel layer CH in contact with the first source/drain electrode SD1 may change, resulting in forming the first ohmic contact region OC1. As an example, a thermal treatment process (e.g., rapid thermal annealing (RTA)) may be used for forming the first ohmic contact region OC1.

While the etching process is performed, the top surface of the channel layer CH and the top surface of the buffer layer 110 may be partially exposed, and the bottom surface of the first photoresist pattern PR1 may be partially exposed.

Referring to FIG. 2, FIG. 11, and FIG. 12, after the etching process is performed, a second source/drain layer SDL2 may be deposited through a deposition process S400. As an example, the deposition process of the second source/drain layer SLD2 may be physical vapor deposition, chemical vapor deposition, atomic layer deposition, or electron beam deposition. The second source/drain layer SDL2 may include a metal material. As an example, the metal material may include at least one of copper (Cu), molybdenum (Mo), titanium (Ti), tantalum (Ta), nickel (Ni), gold (Au), silver (Ag), aluminum (Al), platinum (Pt), tungsten (W), titanium nitride (TiN), or combinations thereof. As an example, the second source/drain layer SDL2 may include either indium zinc oxide (IZO) or indium tin oxide (ITO), which is a transparent electrode.

The second source/drain layer SDL2 may cover a portion of the top surface of the channel layer CH and the top surface of the buffer layer 110, and may cover the top surface of the first photoresist pattern PR1. In other words, the second source/drain layer SDL2 may not be formed on the top surface of the channel layer CH and the top surface of the buffer layer 110, which are covered by the first photoresist pattern PR1. A first distance LT between the first source/drain electrode SD1 and the second source/drain layer SDL2 may be about 20 nm to about 2500 nm, so that patterns having an interval finer than the degree of resolution of an exposure machine used in the exposure process may be formed.

A second ohmic contact region OC2 may be formed in a region in which the second source/drain layer SDL2 meets the channel layer CH. The channel layer CH including an oxide semiconductor may form an oxygen vacancy when brought into contact with the second source/drain electrode SDL2 including a metal material, and due to the oxygen vacancy, the doping concentration of the channel layer CH in contact with the second source/drain electrode SDL2 may change, resulting in forming the second ohmic contact region OC2. As an example, a thermal treatment process (e.g., rapid thermal annealing (RTA)) may be used for forming the second ohmic contact region OC2.

Referring to FIG. 2, FIG. 13, and FIG. 14, after the second source/drain layer SDL2 is formed, the first photoresist pattern PR1 may be removed S400. As an example, the first photoresist pattern PR1 may be removed through a lift-off process, and the lift-off process may include coating a decomposition agent on a substrate to dissolve the first photoresist pattern PR1.

As the first photoresist pattern PR1 is removed, the second source/drain layer SDL2 on the top surface of the first photoresist pattern PR1 may also be removed, and the top surface of the first source/drain electrode SD1 may be exposed. Since the second source/drain layer SDL2 on the first photoresist pattern PR1 is removed, a portion of the second source/drain layer SDL2 may remain on the channel layer CH and the buffer layer 110.

Referring to FIG. 2, FIG. 15, and FIG. 16, a portion of the second source/drain layer SDL2 may be patterned to form a second source/drain electrode SD2 S400. The etching of the second source/drain layer SDL2 may include coating the top surface of the first source/drain electrode SD1, the channel layer CH, and some of the second source/drain layer SDL2 with a photoresist, performing patterning by irradiating the photoresist with light followed by developing, etching a portion of the second source/drain layer SDL2, and removing the photoresist.

The second source/drain electrode SD2 provided by patterning a portion of the second source/drain layer SDL2 may have a symmetrical shape with the first source/drain electrode SD1. The second source/drain electrode SD2 may be spaced apart from the first source/drain electrode SD1 by the first distance LT in the first direction D1.

Referring to FIG. 2, FIG. 17, and FIG. 18, a gate insulation layer GI and a gate electrode layer GEL may be sequentially deposited on the buffer layer 110, the channel layer CH, and the first and second source/drain electrodes SD1 and SD2 S500. As an example, the deposition of the gate insulation layer GI and the gate electrode layer GEL may be physical vapor deposition, chemical vapor deposition, atomic layer deposition, or electron beam deposition. Each of the gate insulation layer GI and the gate electrode layer GEL may be deposited to a substantially uniform thickness. The gate electrode GEL may include a metal material. As an example, the metal material may include at least one of copper (Cu), molybdenum (Mo), titanium (Ti), tantalum (Ta), nickel (Ni), gold (Au), silver (Ag), aluminum (Al), platinum (Pt), tungsten (W), titanium nitride (TiN), or combinations thereof.

Referring to FIG. 2, FIG. 19, and FIG. 20, after the gate electrode layer GEL is deposited, a photoresist may be coated to form a second photoresist layer PRL2. The second photoresist layer PRL2 may be formed by using, for example, a spin coating process, a slit coating process, or a slit and spin coating process. As an example, the photoresist may include a negative-type photoresist. As an example, the photoresist may include a polymer, a photoacid generator, and a solvent.

Referring to FIG. 2, FIG. 21, and FIG. 22, the second the photoresist layer PRL2 may be planarized to form a second photoresist pattern PR2 S600. As an example, a chemical mechanical planarization (CMP) process may be used for the planarization process. A portion of the top surface of the gate electrode layer GEL may be exposed as a result of the planarization process. The top surface of the second photoresist pattern PR2 may be positioned at the same level as the uppermost surface of the gate electrode layer GEL.

Referring to FIG. 2, FIG. 23, and FIG. 24, the gate electrode layer GEL with the exposed top surface may be etched to form a gate electrode pattern GEP which exposes a portion of the top surface of the gate insulation layer GI S700. As an example, the etching of the gate electrode layer GEL may include a wet etching process or a dry etching process. The gate electrode layer GEL adjacent to the uppermost surface of the gate insulation layer GI may be etched to allow the gate electrode pattern GEP between the gate insulation layer GI and the second photoresist pattern PR2 to remain.

Referring to FIG. 2, FIG. 25, and FIG. 26, after the gate electrode layer GEL adjacent to the uppermost surface of the gate insulation layer GI is etched, the second photoresist pattern PR2 may be removed S800. The removal of the second photoresist pattern PR2 may be performed by an ashing process or a strip process. The removal of the second photoresist pattern PR2 may expose the top surface of the gate electrode pattern GEP.

Referring to FIG. 2, FIG. 27, and FIG. 28, after the second photoresist layer PRL2 is removed, a portion of the gate electrode pattern GEP (see FIG. 26) may be etched to provide a gate electrode GE S900. The portion of the gate electrode pattern GEP (see FIG. 26) may be a portion not vertically overlapping the channel layer CH, and portions formed to be higher than the uppermost surface of the gate insulation layer GI.

The process of etching the portion of the gate electrode pattern GEP (see FIG. 26) may include coating a portion vertically overlapping the channel layer CH between the first and second source/drain electrodes SD1 and SD2 with a photoresist, performing patterning by irradiating the photoresist with light followed by developing, etching a portion of the gate electrode pattern GEP (see FIG. 26), and removing the photoresist.

The etching process may include a wet etching process or a dry etching process. As an example, prior to the etching process, a planarization process may be performed until the uppermost surface of the gate electrode pattern GEP (see FIG. 26) and the uppermost surface of the gate insulation layer GI have substantially the same level.

The gate electrode GE provided by the etching process may have a U-shape in a cross-section taken along the first direction D1 and the third direction D3. The uppermost surface of the gate electrode GE and the uppermost surface of the gate insulation layer GI may be positioned at substantially the same level.

Referring to FIG. 2, FIG. 29, and FIG. 30, after the gate electrode GE is provided, an interlayer insulation layer 120 may be deposited on the gate electrode GE and the gate insulation layer GI S1000. After the interlayer insulation layer 120 is deposited, the top surface of the interlayer insulation layer 120 may become parallel to the top surface of the substrate 100 through a planarization process.

A manufacturing method according to an embodiment of the inventive concept may overcome integration limitation by stacking thin film transistors in a three-dimensional single integrated manner.

The manufacturing method according to an embodiment of the inventive concept may provide a source/drain electrode having an interval finer than the degree of resolution of an exposure machine used in an exposure process.

In a thin film transistor according to an embodiment of the inventive concept, a gate electrode and source/drain electrodes are spaced apart in a direction parallel to a substrate and in a direction perpendicular to the substrate, so that parasitic capacitance between the gate electrode and the source/drain electrodes may be reduced, and accordingly, the performance of the thin film transistor may improve.

Although the present invention has been described with reference to the accompanying drawings, it will be understood by those having ordinary skill in the art to which the present invention pertains that various changes in form and details may be made therein without departing from the spirit and scope of the present invention. Therefore, it is to be understood that the above-described embodiments are exemplary and non-limiting in every respect.

What is claimed is:

1. A thin film transistor comprising:
a substrate;
a channel layer on the substrate;
a first source/drain electrode and a second source/drain electrode spaced apart on the substrate and on the channel layer in a first direction parallel to the substrate;
a gate insulation layer on the substrate, the channel layer, the first source/drain electrode, and the second source/drain electrode; and
a gate electrode on the gate insulation layer between the first and second source/drain electrodes, wherein an uppermost level of the gate electrode is substantially the same as an uppermost level of the gate insulation layer.

2. The thin film transistor of claim 1, further comprising a buffer layer between the substrate and the channel layer, between the substrate and the first and second source/drain electrodes, and between the substrate and the channel layer.

3. The thin film transistor of claim 1, further comprising the channel layer comprises at least one of indium gallium zinc oxide (IGZO), indium zinc tin oxide (IZTO), aluminum-doped indium zinc tin oxide (AIZTO), zinc tin oxide (ZTO), or combinations thereof.

4. The thin film transistor of claim 1, wherein the channel layer comprises a first ohmic contact region adjacent to the first source/drain electrode, and a second ohmic contact region adjacent to the second source/drain electrode.

5. The thin film transistor of claim 1, wherein the gate electrode is spaced apart in a second direction perpendicular to the channel layer and the substrate.

6. The thin film transistor of claim 1, wherein the maximum width of the gate electrode is less than the distance between the first and second source/drain electrodes.

7. The thin film transistor of claim 1, wherein the thickness of the gate insulation layer is substantially uniform.

8. The thin film transistor of claim 1, wherein the length of the channel layer between the first source/drain electrode and the second source/drain electrode is approximately 20 nm to approximately 2500 nm.

9. The thin film transistor of claim 1, further comprising an interlayer insulation layer on the gate electrode and the gate insulation layer.

10. The thin film transistor of claim 1, wherein a lowermost level of the gate electrode is lower than the uppermost level of the first and second source/drain electrodes.

11. A method for manufacturing a thin film transistor, the method comprising:
sequentially stacking a channel layer and a first source/drain layer on a substrate;
patterning the first source/drain layer to form a first source/drain electrode on the substrate and the channel layer;
forming a second source/drain electrode spaced apart from the first source/drain electrode on the channel layer;
sequentially stacking a gate insulation layer and a gate electrode layer on the channel layer and the first and second source/drain electrodes; and
etching a portion of the gate electrode layer to form a gate electrode on the gate insulation layer between the first and second source/drain electrodes, wherein the uppermost level of the gate electrode is substantially the same as the uppermost level of the gate insulation layer.

12. The method of claim 11, wherein the forming of the first source/drain electrode comprises:
coating the first source/drain layer with a photoresist and irradiating the same with light to form a first photoresist pattern; and
etching the first source/drain layer by using the first photoresist pattern as an etch mask to form the first source/drain electrode which partially covers the channel layer and the substrate.

13. The method of claim 12, wherein the forming of the second source/drain electrode comprises:
after the forming of the first source/drain electrode, depositing a second source/drain layer;
removing the first photoresist pattern; and
etching the second source/drain layer to form the second source/drain electrode.

14. The method of claim 12, wherein the photoresist comprises a negative-type photoresist.

15. The method of claim 13, wherein the length of the channel layer between the first source/drain electrode and the second source/drain electrode is approximately 20 nm to approximately 2500 nm.

16. The method of claim 11, wherein the channel layer comprises an oxide semiconductor.

17. The method of claim 16, further comprising:
after the forming of the first source/drain electrode, forming a first ohmic contact region in the channel layer adjacent to the first source/drain electrode through a heat treatment process; and
after the forming of the second source/drain electrode, forming a second ohmic contact region in the channel layer adjacent to the second source/drain electrode through a heat treatment process.

18. The method of claim 11, further comprising, before the stacking of the channel layer, stacking a buffer layer on the substrate.

19. The method of claim 11, wherein the forming of the gate electrode comprises:
forming a second photoresist layer which covers the gate electrode layer;
planarizing the second photoresist layer to form a second photoresist pattern which exposes the uppermost surface of the gate electrode layer;
etching a portion of the gate electrode layer by using the second photoresist pattern as an etch mask to expose the uppermost surface of the gate insulation layer and to form a gate electrode pattern;
removing the second photoresist pattern; and
etching the gate electrode pattern to form the gate electrode between the first and second source/drain electrodes.

20. The method of claim 11, further comprising stacking an interlayer insulation layer on the gate electrode and the gate insulation layer.
